(19) United States
(12) Patent Application Publication
(10) Pub. No.: US 2025/0086367 A1
(43) Pub. Date: Mar. 13, 2025

(54) SYSTEM AND METHOD FOR PERFORMING FIELD PROGRAMMABLE GATE ARRAY PROTOTYPE VERIFICATION ON TESTED CIRCUIT

(71) Applicant: Realtek Semiconductor Corp., HsinChu (TW)

(72) Inventors: Jiaxuan Cai, Suzhou City (CN); Fei Yan, Suzhou City (CN); Qiang yu, Suzhou City (CN); Yaoyi Wang, Suzhou City (CN)

(73) Assignee: Realtek Semiconductor Corp., HsinChu (TW)

(21) Appl. No.: 18/827,880

(22) Filed: Sep. 9, 2024

(30) Foreign Application Priority Data
Sep. 12, 2023 (CN) 202311174368.5

(51) Int. Cl. G06F 30/33; G06F 30/34; H04L 25/03

(52) U.S. Cl. CPC G06F 30/33; G06F 30/34; H04L 25/03866

(57) ABSTRACT

A system and a method for performing field programmable gate array (FPGA) prototype verification on a tested circuit are provided. The system includes a packet generator, a scrambling circuit, the tested circuit and a checking circuit, wherein the scrambling circuit, the tested circuit and the checking circuit are implemented on an FPGA. The packet generator outputs multiple standard packets, wherein a length of each standard packet falls within a standard range. The scrambling circuit generates multiple scrambled packets according to the multiple standard packets to the tested circuit, to make the tested circuit generate multiple output packets according to the multiple scrambled packets, wherein a length of any scrambled packet falls outside the standard range. The checking circuit verifies operations of the tested circuit according to the multiple scrambled packets and the output packets.

### BACKGROUND OF THE INVENTION

### 1. Field of the Invention

The present invention is related to network communication chips, and more particularly, to a system and a method for performing field programmable gate array (FPGA) prototype verification on a tested circuit (e.g. a prototype circuit of a switch chip).

### 2. Description of the Prior Art

In network communication systems, switches serve as core roles in data transfer. Thus, reliability of a switch chip is an important precondition to allow an overall communication system to properly work. Packets of a transmitting terminal of the switch chip are generated internally, which is relatively controllable and less likely to have errors. Packets of a receiving terminal of the switch chip are from various types of external devices, which cannot be controlled by internal software/hardware, and are therefore more likely to have unpredictable errors.

Conventional field programmable gate array (FPGA) verification methods utilize an IXIA network testing device to generate packets which have lengths and inter-packet gaps (IPGs) falling in corresponding standard ranges. The packets are then transmitted to a receiving terminal of a prototype circuit of the switch chip (referred to as a switch prototype circuit), in order to check a handling ability of the switch prototype circuit for the packets. The switch chip may receive packets of various erroneous lengths or erroneous IPGs in real conditions. As a result, due to limitations of the IXIA network testing device utilized in the conventional verification methods, the related art is unable to check whether the switch chip can properly handle the packets when packet format(s) is incorrect.

Thus, there is a need for a novel method and associated system architecture, which can emulate various erroneous packets (e.g. packets having erroneous length or erroneous IPG) received by the switch chip in a FPGA as much as possible without introducing any side effect or in a way that is less likely to introduce side effects, thereby improving robustness of operations of the switch chip.

### SUMMARY OF THE INVENTION

An objective of the present invention is to provide a system and a method for performing field programmable gate array (FPGA) prototype verification on a tested circuit (e.g. a prototype circuit of a switch chip), in order to ensure that the tested circuit can properly operate when permutations and combinations of various packets (e.g. packets having various lengths or various IPGs) are received.

At least one embodiment of the present invention provides a system for performing FPGA prototype verification on a tested circuit. The system comprises a packet generator, a scrambling circuit, the tested circuit and a checking circuit, where the scrambling circuit is coupled to the packet generator and the tested circuit, and the checking circuit is coupled to the scrambling circuit and the tested circuit. The packet generator is configured to output one or more standard packets, where a length of each of the one or more standard packets falls within a standard range. The scrambling circuit is configured to receive the one or more standard packets, and generate one or more scrambled packets according to the one or more standard packets for being output to the tested circuit, to make the tested circuit generate one or more output packets according to the one or more scrambled packets, where a length of any of the one or more scrambled packets falls outside the standard range. The checking circuit is configured to receive the one or more scrambled packets and the one or more output packets, and verify operations of the tested circuit according to the one or more scrambled packets and the one or more output packets. More particularly, the scrambling circuit, the tested circuit and the checking circuit are implemented on an FPGA.

At least one embodiment of the present invention provides a method for performing FPGA prototype verification on a tested circuit. The method comprises: utilizing a packet generator to output one or more standard packets, where a length of each of the one or more standard packets falls within a standard range; utilizing a scrambling circuit to receive the one or more standard packets and generate one or more scrambled packets according to the one or more standard packets, where a length of any of the one or more scrambled packets falls outside the standard range; utilizing the tested circuit to receive the one or more scrambled packets and generate one or more output packets according to the one or more scrambled packets; and utilizing a checking circuit to receive the one or more scrambled packets and the one or more output packets, and utilizing a checking circuit to verify operations of the tested circuit according to the one or more scrambled packets and the one or more output packets. In addition, the scrambling circuit, the tested circuit and the checking circuit are implemented on an FPGA.

The system and the method provided by the embodiments of the present invention further configure the scrambling circuit on the FPGA to generate the scrambled packets having various lengths and various inter-packet gaps (IPGs), thereby enabling processing conditions of the switch chip receiving various types of packets to be completely verified. In addition, the embodiments of the present invention will not greatly increase additional costs. Thus, the present invention can ensure robustness of operations of the switch chip without introducing any side effect or in a way that is less likely to introduce side effects.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a system for performing field programmable gate array (FPGA) prototype verification on a tested circuit according to an embodiment of the present invention.

FIG. 2 is a diagram illustrating a working flow of a method for performing FPGA prototype verification on the tested circuit shown in FIG. 1 according to an embodiment of the present invention.

FIG. 3 is a diagram illustrating an example of the working flow shown in FIG. 2 according to an embodiment of the present invention.

FIG. 4A is a diagram illustrating a portion of a working flow of scrambling lengths of packets according to an embodiment of the present invention.

FIG. 4B is a diagram illustrating another portion of a working flow of scrambling lengths of packets according to an embodiment of the present invention.

FIG. 4C is a diagram illustrating yet another portion of a working flow of scrambling lengths of packets according to an embodiment of the present invention.

FIG. 5 is a diagram illustrating a packet format of a standard packet according to an embodiment of the present invention.

FIG. 6 is a diagram illustrating a working flow of scrambling contents of a destination address field and a source address field of a standard packet according to an embodiment of the present invention.

FIG. 7 is a diagram illustrating a control scheme of a scrambling circuit when operating in a certain mode according to an embodiment of the present invention.

### DETAILED DESCRIPTION

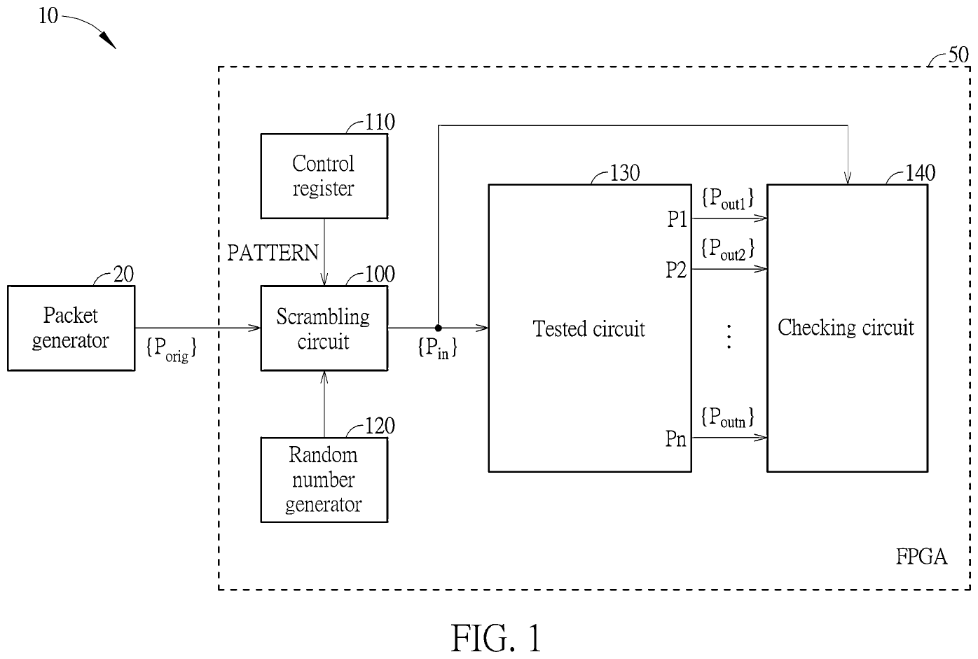

FIG. 1 is a diagram illustrating a system 10 for performing field programmable gate array (FPGA) prototype verification on a tested circuit 130 according to an embodiment of the present invention, where the system 10 may comprise the tested circuit 130, and the tested circuit 130 may represent a prototype circuit of a switch chip. In this embodiment, the system 10 may further comprise a packet generator 20 (e.g. an IXIA network testing device), a scrambling circuit 100, a control register 110, a random number generator 120 and a checking circuit 140, where the scrambling circuit 100, the control register 110, the random number generator 120 and the checking circuit 140 may be implemented on an FPGA 50. As shown in FIG. 1, the scrambling circuit 100 is coupled to the packet generator 20, the control register 110, the random number generator 120 and the tested circuit 130, and the checking circuit 140 is coupled to the scrambling circuit 100 and the tested circuit 130. In detail, the packet generator 20 may be configured to output one or more standard packets such as standard packets {P_{orig}}, where a length of each standard packet P_{orig} of the standard packets {P_{orig}} falls within a standard range. For example, the length of each standard packet P_{orig} of the standard packets {P_{orig}} and an inter-packet gap (IPG) such as a gap between any two packets conforms to a specific network communication specification. The scrambling circuit 100 may be configured to receive the standard packets {P_{orig}} and generate one or more scrambled packets such as scrambled packets {Pᵢₙ} to the tested circuit 130, to make the tested circuit 130 generate one or more output packets such as n output packets {Pₒᵤₜ₁}, {Pₒᵤₜ₂}, . . . and {Pₒᵤₜₙ} output from n ports P1, P2, . . . and Pn of the tested circuit 130, where n is a positive integer, and a length of any scrambled packet Pᵢₙ of the scrambled packets {Pᵢₙ} falls outside the standard range.

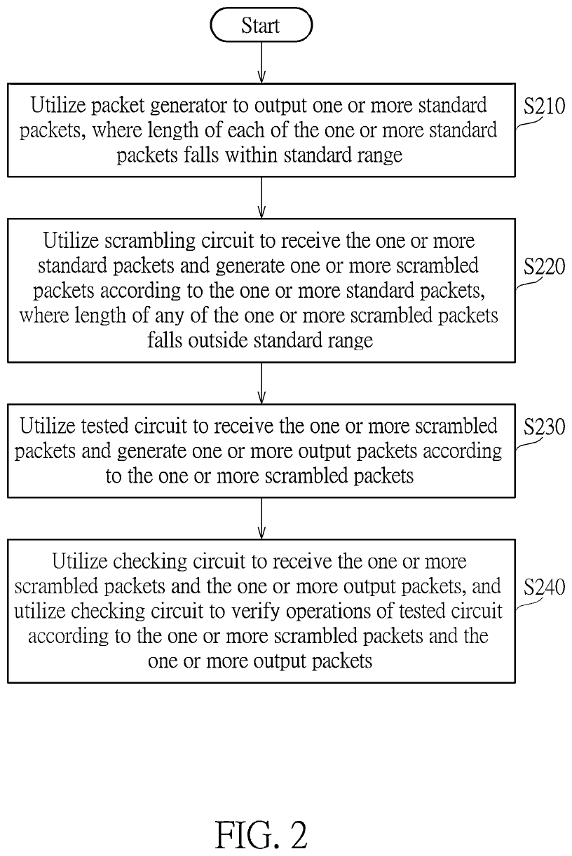

FIG. 2 is a diagram illustrating a working flow of a method for performing FPGA prototype verification on the tested circuit 130 shown in FIG. 1 according to an embodiment of the present invention. It should be noted that the working flow shown in FIG. 2 is for illustrative purposes only, and is not meant to be a limitation of the present invention. For example, one or more steps may be added, deleted or modified in the working flow shown in FIG. 2. In addition, if an overall result is the same, these steps do not have to be executed in the exact order shown in FIG. 2.

In Step S210, the system 10 may utilize the packet generator 20 to output one or more standard packets (e.g. the standard packets {P_{orig}}), where a length of each of the one or more standard packets falls within a standard range.

In Step S220, the system 10 may utilize the scrambling circuit 100 to receive the one or more standard packets and generate one or more scrambled packets (e.g. the scrambled packets {Pᵢₙ}) according to the one or more standard packets, where a length of any of the one or more scrambled packets falls outside the standard range.

In Step S230, the system 10 may utilize the tested circuit 130 to receive the one or more scrambled packets and generate one or more output packets (e.g. the output packets {Pₒᵤₜ₁}, {Pₒᵤₜ₂}, . . . and {Pₒᵤₜₙ}) according to the one or more scrambled packets.

In Step S240, the system 10 may utilize the checking circuit 140 to receive the one or more scrambled packets and the one or more output packets, and utilize the checking circuit 140 to verify operations of the tested circuit 130 according to the one or more scrambled packets and the one or more output packets.

The scrambled packets {Pᵢₙ} may comprise one or more of at least one split packet, at least one short packet, at least one long packet and at least one normal packet. In detail, the scrambling circuit 100 may split up at least one standard packet P_{orig} of the standard packets {P_{orig}} into multiple split packets, where a length of each split packet of the multiple split packets is less than a minimum length within the standard range, and each split packet may be an example of the scrambled packet Pᵢₙ. For example, when a minimum packet length and a maximum packet length defined in the specific network communication specification are 64 bytes and 1518 bytes, respectively, the length of each split packet of the multiple split packets is less than 64 bytes. In addition, the scrambling circuit 100 may reduce a length of at least one standard packet P_{orig} of the standard packets {P_{orig}} by one byte to generate at least one short packet, where the at least one short packet may be an example of the scrambled packet Pᵢₙ. For example, the scrambling circuit 100 may discard one byte of a certain standard packet P_{orig} which has a length equal to orig_len bytes, to generate a short packet which has a length equal to (orig_len−1) bytes. In addition, the scrambling circuit 100 may connect multiple standard packets P_{orig} of the standard packets {P_{orig}} into at least one long packet, where a length of the at least one long packet may be greater than a maximum length within the standard range, and the at least one long packet may be an example of the scrambled packet Pᵢₙ. For example, when the minimum packet length and the maximum packet length defined in the specific network communication specification are 64 bytes and 1518 bytes, respectively, the scrambling circuit 100 may connect a specific number or more of standard packets P_{orig} into a long packet, to make a length of the long packet be greater than 1518 bytes. In addition, the scrambling circuit 100 may directly output any standard packet P_{orig} of the standard packets {P_{orig}} to be a normal packet without any scrambling processes, where the normal packet may be an example of the scrambled packet Pᵢₙ. For example, the scrambling circuit 100 may directly output a certain standard packet P_{orig} having a length equal to orig_len bytes, to be a normal packet having a length equal to orig_len bytes.

As mentioned above, the scrambling circuit 100 may generate different types of scrambled packets Pᵢₙ such as the split packet, the short packet, the long packet and the normal packet. In this embodiment, the scrambling circuit 100 may receive a pattern control signal PATTERN from the control register 110, in order to determine a scrambling pattern executed by the scrambling circuit 100 according to the pattern control signal PATTERN, where different scrambling patterns may correspond to permutations and combinations of different types of scrambled packets Pᵢₙ mentioned above. For example, the pattern control signal PATTERN may be a 4-bit binary value (which may be illustrated by 4′bxxxx). When PATTERN=4′b0000, the scrambling circuit 100 may prevent scrambling a packet length, in order to keep the packet length unchanged (e.g. the length of the scrambled packet Pᵢₙ is equal to the length of the standard packet P_{orig}). When PATTERN=4′b0001, the scrambling circuit 100 may generate a lot of split packets and few normal packets (e.g. a number of the split packets is greater than a number of the normal packets). When PATTERN=4′b0010, the scrambling circuit 100 may generate one split packet and one normal packet following the split packet. When PATTERN=4′b0011, the scrambling circuit 100 may generate two split packets and two normal packets following the two split packets. When PATTERN=4′b0100, the scrambling circuit 100 may generate a lot of short packets and few normal packets (e.g. a number of the short packets is greater than a number of the normal packets). When PATTERN=4′b0101, the scrambling circuit 100 may iteratively generate the short packets and the normal packets (e.g. each short packet is followed by one normal packet). When PATTERN=4′b0110, the scrambling circuit 100 may generate a lot of long packets and few normal packets (e.g. a number of the long packets is greater than a number of the normal packets). When PATTERN=4′b0111, the scrambling circuit 100 may iteratively generate long packets and normal packets (e.g. each long packet is followed by one normal packet). When PATTERN=4′b1000, the scrambling circuit 100 may iteratively generate long packets and short packets (e.g. each long packet is followed by one short packet). When PATTERN=4′b1001, the scrambling circuit 100 may periodically generate following packet combinations: one long packet followed by one split packet or one normal packet, where the random number generator 120 may generate a random number to control whether the packet following the long packet is the split packet or the normal packet.

It should be noted that details of controlling an operation pattern of the scrambling circuit 100 by the pattern control signal PATTERN is for illustrative purposes only, and is not meant to be a limitation of the present invention. For example, the pattern control signal PATTERN may be a binary value having a bit count more than 4 bits or a binary value having a bit count less than 4 bits. In another example, permutations and combinations of scrambled packets corresponding to respective values may vary. In addition, the lengths of the split packet and/or the long packet may be controlled by random numbers. For example, the scrambling circuit 100 may split up the standard packet P_{orig} into multiple split packets according to multiple random numbers within a predetermined range (e.g. the random number generator 120 generates multiple random numbers within an interval [0, 63] under a condition where the minimum packet length and the maximum packet length defined in the specific network communication specification are 64 bytes and 1518 bytes, respectively), to make lengths of the multiple split packets be respectively equal to the multiple random numbers (e.g. making the lengths of the multiple split packets be randomly distributed). In another example, the scrambling circuit 100 may connect multiple standard packets P_{orig} into the at least one long packet according to at least one random number within a predetermined range (e.g. the random number generator 120 generates at least one random number within an interval [1519, max_long_len] under a condition where the minimum packet length and the maximum packet length defined in the specific network communication specification are 64 bytes and 1518 bytes, respectively, where max_long_len may represent a positive integer greater than 1519, and may be written into at least one register within the random number generator 120), to make a length of the at least one long packet be equal to the at least one random number. In some embodiment, the lengths of the split packet and/or the long packet may be controlled by fixed numbers. For example, the scrambling circuit 100 may split up the standard packet P_{orig} into multiple split packets according to a split packet fixed number within the interval [0, 63], to make the length of each of the multiple split packets be equal to the split packet fixed number, where the split packet fixed number may be written into at least one register within the scrambling circuit 100, but the present invention is not limited thereto. In another example, the scrambling circuit 100 may connect a corresponding number of standard packets P_{orig} into the at least one long packet according to a long packet fixed number within the interval [1519, max_long_len], to make the length of the at least one long packet be equal to the long packet fixed number, where the long packet fixed number may be written into at least one register within the scrambling circuit 100.

In some embodiments, the scrambling circuit 100 may split up the standard packet P_{orig} into the multiple split packets according to at least one IPG random number within an IPG predetermined range, to make a gap between any two adjacent split packets of the multiple split packets be equal to the at least one IPG random number. For example, the random number generator 120 may generate the at least one IPG random number within an interval [ipg_min, ipg_max], to allow the scrambling circuit 100 to split up the standard packet P_{orig} into the multiple split packets according to the at least one IPG random number, making gaps between any two adjacent split packets be randomly distributed in the interval [ipg_min, ipg_max]. In some embodiment, the scrambling circuit 100 may split up the standard packet P_{orig} into the multiple split packets according to an IPG fixed number, to make the gaps of each set of adjacent split packets of the multiple split packets be equal to the IPG fixed number.

In some embodiments, when the scrambling circuit 100 splits up the standard packet P_{orig} into the multiple split packets, the scrambling circuit 100 may directly apply a source address of the standard packet P_{orig} to a source addresses of each of the split packets, and directly apply a destination address of the standard packet P_{orig} to a destination address of each of the split packets. In some embodiments, the scrambling circuit 100 may replace the source address of the standard packet P_{orig} with a replacement source address to determine a source address of at least one split packet of the multiple split packets, and/or replace the destination address of the standard packet P_{orig} with a replacement destination address to determine a destination address of the at least one split packet of the multiple split packets.

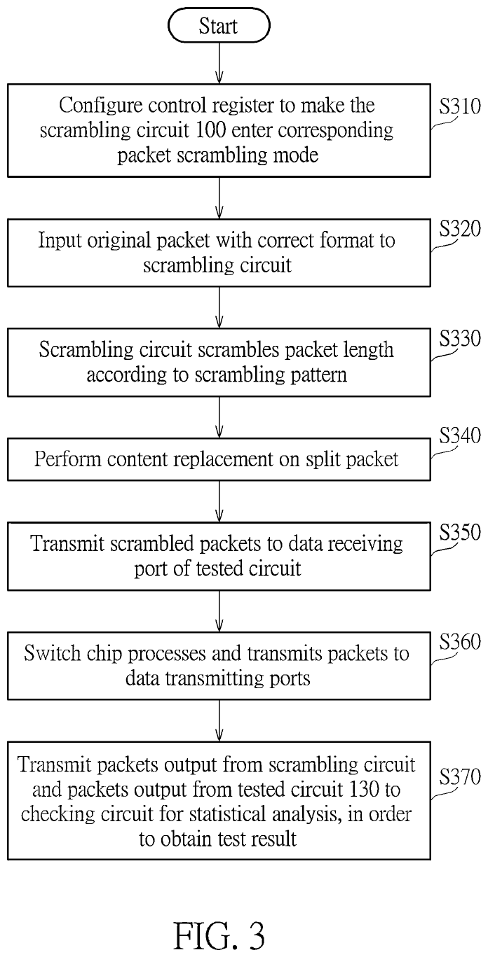

FIG. 3 is a diagram illustrating an example of the working flow shown in FIG. 2 based on scrambling operations, length scrambling and content scrambling mentioned above according to an embodiment of the present invention. It should be noted that the working flow is for illustrative purposes only, and is not meant to be a limitation of the present invention. For example, one or more steps may be added, deleted or modified in the working flow shown in FIG. 3. In addition, if an overall result is the same, these steps do not have to be executed in the exact order shown in FIG. 3.

In Step S310, the system 10 may configure the control register 110 (e.g. setting a value of the pattern control signal PATTEN) to make the scrambling circuit 100 enter a corresponding packet scrambling mode.

In Step S320, the system 10 may control the packet generator 20 to input an original packet with a correct format (e.g. the standard packet P_{orig} conforming to the specific network communication specification) to the scrambling circuit 100.

In Step S330, the system 10 may control the scrambling circuit 10 to scramble a packet length according to a scrambling pattern thereof (e.g. according to the pattern control signal PATTERN).

In Step S340, the system 10 may control the scrambling circuit 100 to perform content replacement on a split packet (e.g. replacing original source/destination addresses of the standard packet P_{orig} by specific source/destination addresses).

In Step S350, the system 10 may control the scrambling circuit 100 to transmit the scrambled packets {Pᵢₙ} to a data receiving port of the tested circuit 130.

In Step S360, the system 10 may control the tested circuit 130 (e.g. the prototype circuit of the switch chip) to process and transmit packets (e.g. the scrambled packets {Pᵢₙ}) to data transmitting ports (e.g. the ports P1, P2, . . . and Pn).

In Step S370, the system 10 may transmit the packets output from the scrambling circuit 100 (e.g. the scrambled packets {Pᵢₙ}) and the packets output from the tested circuit 130 (e.g. the output packets {Pₒᵤₜ₁}, {Pₒᵤₜ₂}, . . . and {Pₒᵤₜₙ} respectively output from the ports P1, P2, . . . and Pn) to the checking circuit 140 for statistical analysis, in order to obtain a test result.

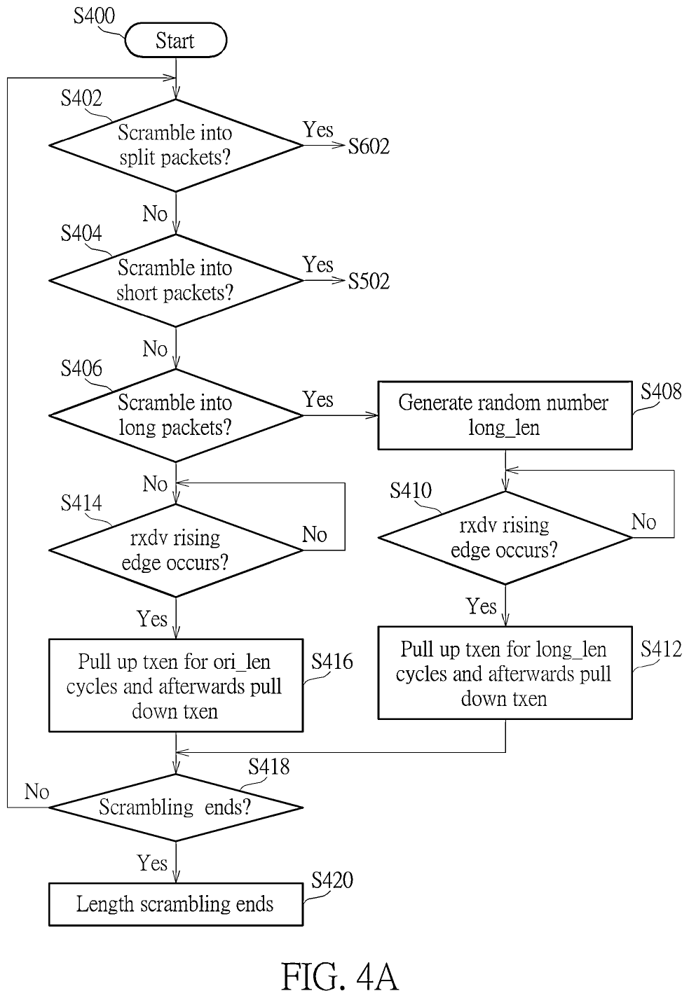

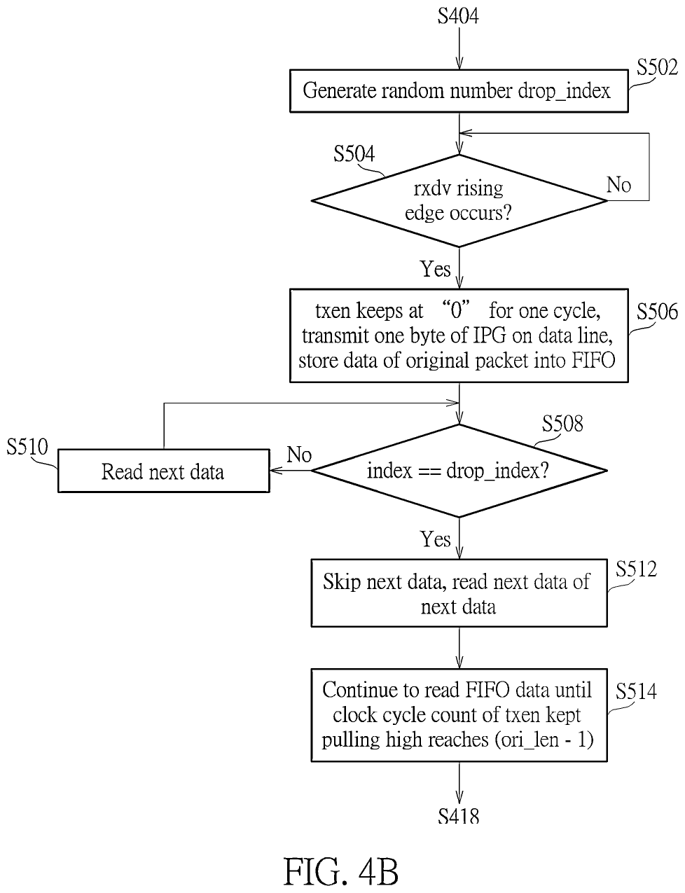

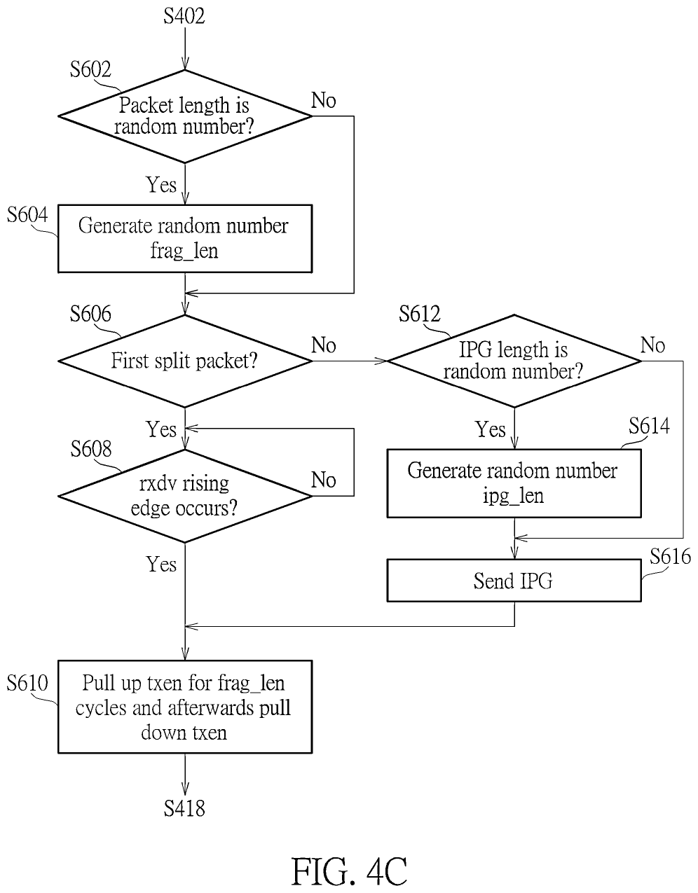

FIG. 4A is a diagram illustrating a portion of a working flow of scrambling lengths of packets according to an embodiment of the present invention, FIG. 4B is a diagram illustrating another portion of the working flow of scrambling lengths of packets according to an embodiment of the present invention, and FIG. 4C is a diagram illustrating yet another portion of the working flow of scrambling lengths of packets according to an embodiment of the present invention. It should be noted that the working flow shown in FIG. 4A, FIG. 4B and/or FIG. 4C is for illustrative purposes only, and is not meant to be a limitation of the present invention. For example, one or more steps may be added, deleted or modified in the working flow shown in FIG. 4A, FIG. 4B and/or FIG. 4C. In addition, if an overall result is the same, these steps do not have to be executed in the exact order shown in FIG. 4A, FIG. 4B and/or FIG. 4C.

Please refer to FIG. 4A, where FIG. 4A shows Steps S400, S402, S404, S406, S408, S410, S412, S414, S416, S418 and S420 as follows.

In Step S400, the packet generator 20 may generate the standard packets {P_{orig}} and transmit the standard packets {P_{orig}} to the scrambling circuit 100, and the working flow starts.

In Step S402, the scrambling circuit 100 may determine whether to scramble the received standard packets P_{orig} into split packets according to the pattern control signal PATTERN or a derivative signal thereof. If the determination result shows “Yes”, the working flow proceeds with Step S602. If the determination result shows “No”, the working flow proceeds with Step S404.

In Step S404, the scrambling circuit 100 may determine whether to scramble the received standard packets P_{orig} into short packets according to the pattern control signal PATTERN or the derivative signal thereof. If the determination result shows “Yes”, the working flow proceeds with Step S502. If the determination result shows “No”, the working flow proceeds with Step S406.

In Step S406, the scrambling circuit 100 may determine whether to scramble the received standard packets P_{orig} into long packets according to the pattern control signal PATTERN or the derivative signal thereof. If the determination result shows “Yes”, the working flow proceeds with Step S408. If the determination result shows “No”, the working flow proceeds with Step S414.

In Step S408, the random number generator 120 may generate a random number long_len.

In Step S410, the scrambling circuit 100 may determine whether a rising edge of a receiving control signal rxdv occurs. If the determination result shows “Yes” (which means the scrambling circuit 100 starts receiving and connecting multiple standard packets P_{orig}), the working flow proceeds with Step S412. If the determination result shows “No”, the working flow returns to Step S410 to perform this determination again.

In Step S412, the scrambling circuit 100 may pull up a transmitting control signal txen at the moment of occurrence of the rising edge of the receiving control signal rxdv, to indicate that the scrambling circuit 100 starts transmitting the long packet, and more particularly, may keep the transmitting control signal txen at a high level for long_len cycles and afterwards pull down the transmitting control signal txen, to make the scrambling circuit 100 send the long packet having a length equal to long_len.

In Step S414, the scrambling circuit 100 may determine whether a rising edge of the receiving control signal rxdv occurs. If the determination result shows “Yes” (which means the scrambling circuit 100 starts receiving and the standard packet P_{orig} having a length equal to ori_len, and the standard packet P_{orig} is directly output as a normal packet), the working flow proceeds with Step S416. If the determination result shows “No”, the working flow returns to Step S414 to perform this determination again.

In Step S416, the scrambling circuit 100 may pull up the transmitting control signal txen at the moment of occurrence of the rising edge of the receiving control signal rxdv, to indicate that the scrambling circuit 100 starts transmitting the normal packet, and more particularly, may keep the transmitting control signal txen at the high level for ori_len cycles and afterwards pull down the transmitting control signal txen, to make the scrambling circuit 100 send the normal packet having a length equal to ori_len.

In Step S418, the scrambling circuit 100 may determine whether the operation of scrambling the packet length ends according to the pattern control signal PATTERN or the derivative signal thereof. If the determination result shows “Yes”, the working flow proceeds with Step S420. If the determination result shows “No”, the working flow proceeds with Step S402.

Please refer to FIG. 4B, where FIG. 4B shows Steps S502, S504, S506, S508, S510, S512 and S514. The operation of the steps is detailed as follows.

In Step S502, the random number generator 120 may generate a random number drop_index.

In Step S504, the scrambling circuit 100 may determine whether a rising edge of the receiving control signal rxdv occurs. If the determination result shows “Yes” (which means the scrambling circuit 100 starts receiving and the standard packet P_{orig} having a length equal to ori_len), the working flow proceeds with Step S506. If the determination result shows “No” (which means the scrambling circuit 100 does not start receiving the standard packet P_{orig} yet), the working flow returns to Step S504 to perform this determination again.

In Step S506, the scrambling circuit 100 may make the transmitting control signal txen be kept at a low level (e.g. “0”) for one cycle after occurrence of the rising edge of the receiving control signal rxdv, to transmit one byte of IPG on a data line, and store data of an original packet (e.g. data of the standard packet P_{orig}) into a first-in first-out register (FIFO).

In Step S508, the scrambling circuit 100 may determine whether a present index value index is equal to drop_index (labeled “index==drop_index?” in FIG. 4B for brevity). If the determination result shows “Yes” (which means data corresponding to the present index value index is byte data to be discarded), the working flow proceeds with Step S512. If the determination result shows “No” (which means the data corresponding to the present index value index is not the byte data to be discarded), the working flow proceeds with Step S510.

In Step S510, the scrambling circuit 100 may read next data.

In Step S512, the scrambling circuit 100 may skip the next data (i.e. discard and not read the byte data corresponding to the present index value index) and then read next data of the next data.

In Step S514, the scrambling circuit 100 may continue to read remaining data within the FIFO until a clock cycle count of the transmitting control signal txen kept pulling high reaches (ori_len−1), to make the scrambling circuit 100 output a short packet having a length equal to (ori_len−1) bytes.

Please refer to FIG. 4C, where FIG. 4C shows Steps S602, S604, S606, S608, S610, S612, S614 and S616, and the operation of the steps is detailed as follows.

In Step S602, the scrambling circuit 100 may determine whether the packet length is a random number according to the pattern control signal PATTERN or the derivative signal thereof. If the determination result shows “Yes”, the working flow proceeds with Step S604. If the determination result shows “No”, the working flow proceeds with Step S606.

In Step S604, the random number generator 120 may generate a random number frag_len.

In Step S606, the scrambling circuit 100 may determine whether a split packet generated at a present time is a first split packet. If the determination result shows “Yes”, the working flow proceeds with Step S608. If the determination result shows “No”, the working flow proceeds with Step S612.

In Step S608, the scrambling circuit 100 may determine whether a rising edge of the receiving control signal rxdv occurs. If the determination result shows “Yes” (which means the scrambling circuit 100 starts receiving and splits up the standard packet P_{orig} into split packets), the working flow proceeds with Step S610. If the determination result shows “No” (which means the scrambling circuit 100 does not start receiving the standard packet P_{orig} yet), the working flow returns to Step S608 to perform this determination again.

In Step S610, the scrambling circuit 100 may pull up the transmitting control signal txen at the moment of occurrence of the rising edge of the receiving control signal rxdv, to indicate that the scrambling circuit 100 starts transmitting the split packet, and more particularly, may keep the transmitting control signal txen at the high level for frag_len cycles and afterwards pull down the transmitting control signal txen, in order to make the scrambling circuit 100 send the split packet having a length equal to frag_len.

In Step S612, the scrambling circuit 100 may determine whether an IPG length is a random number according to the pattern control signal PATTERN or the derivative signal thereof. If the determination result shows “Yes”, the working flow proceeds with Step S614. If the determination result shows “No”, the scrambling circuit 100 takes a default value as the IPG length, and the working flow proceeds with Step S616.

In Step S614, the random number generator 120 may generate a random number ipg_len, to allow the scrambling circuit 100 to take the random number ipg_len as the IPG length.

In Step S616, the scrambling circuit 100 may send an IPG.

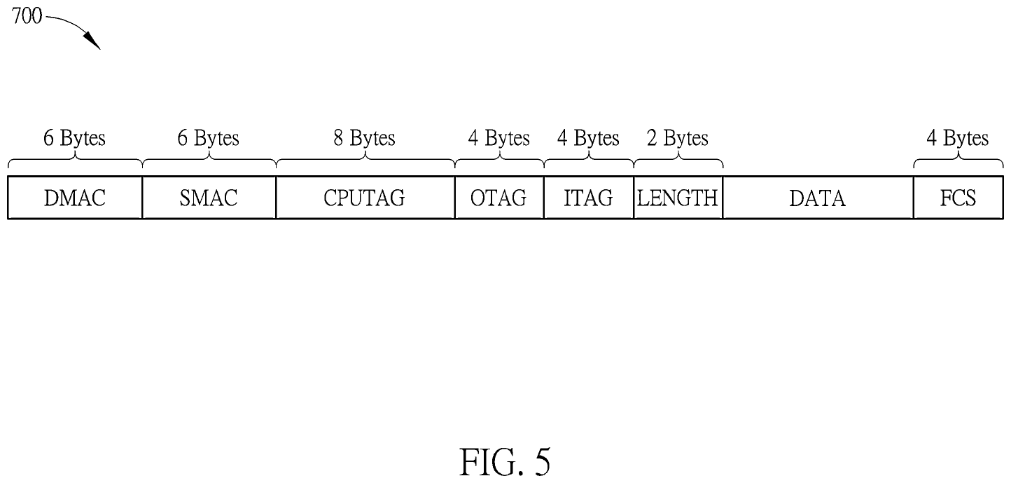

FIG. 5 is a diagram illustrating a packet format 700 of the standard packet P_{orig} according to an embodiment of the present invention. As shown in FIG. 5, the packet format 700 of the standard packet P_{orig} may comprise multiple fields such as a destination address field DMAC, a source address field SMAC, multiple tag fields such as CPUTAG, OTAG and ITAG, a length field LENGTH, a data field DATA and a check field FCS. In some embodiments, the scrambling circuit 100 may scramble contents of the destination address field DMAC and the source address field SMAC of the standard packet P_{orig}.

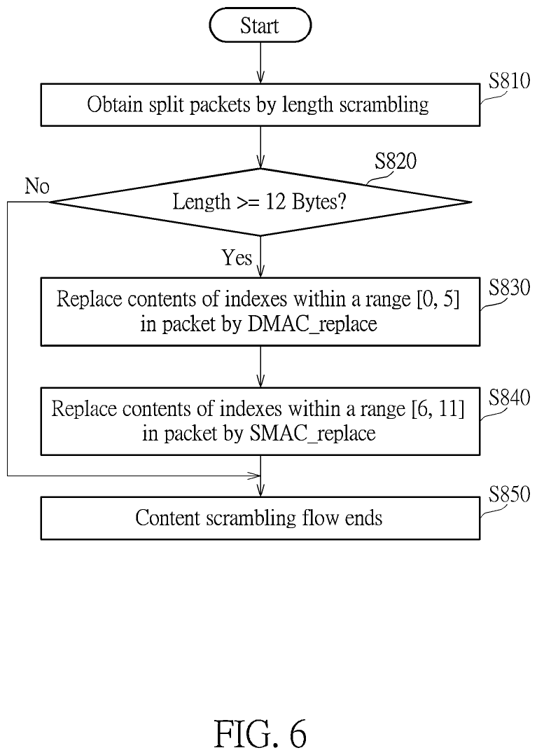

In particular, the embodiments of the present invention intend to test whether the prototype circuit of the switch chip is able to identify addresses of all scrambled packets or not. As the split packets are obtained by splitting up the standard packets P_{orig}, most of the split packets do not have their own address information, and address information of each split packet is obtained by copying partial information of an original packet (e.g. the standard packet P_{orig}). As for the split packets which do not have their own address information but have lengths meeting predetermined conditions, the scrambling circuit 100 may scramble the contents as shown in FIG. 6. FIG. 6 is a diagram illustrating a working flow of scrambling contents of the destination address field DMAC and the source address field SMAC of the standard packet P_{orig} according to an embodiment of the present invention. It should be noted that the working flow shown in FIG. 6 is for illustrative purposes only, and is not meant to be a limitation of the present invention. For example, one or more steps may be added, deleted or modified in the working flow shown in FIG. 6. In addition, if an overall result is the same, these steps do not have to be executed in the exact order shown in FIG. 6.

In Step S810, the scrambling circuit 100 may obtain split packets by length scrambling.

In Step S820, the scrambling circuit 100 may determine whether a length of a split packet is greater than a predetermined byte count (e.g. a total byte count of the destination address field DMAC and the source address field SMAC, such as 12 bytes). If the determination result shows “Yes” (which means this split packet has complete destination address field DMAC and source address field SMAC), the working flow proceeds with Step S830. If the determination result shows “No” (which means this split packet does not have complete destination address field DMAC and source address field SMAC and is unable to undergo address replacement), the working flow proceeds with Step S850.

In Step S830, the scrambling circuit 100 may replace contents corresponding to indexes within a range [0, 5] (e.g. contents of a first byte to a sixth byte) in the split packet by DMAC_replace (e.g. replacing the destination address field DMAC shown in FIG. 5 by DMAC_replace).

In Step S840, the scrambling circuit 100 may replace contents corresponding to indexes within a range [6, 11] (e.g. contents of a seventh byte to a twelfth byte) in the split packet by SMAC_replace (e.g. replacing the source address field SMAC shown in FIG. 5 by SMAC_replace).

In Step S850, the scrambling circuit 100 finishes content scrambling of the destination address field DMAC and the source address field SMAC mentioned above.

In order to verify that the switch chip would not malfunction when receiving a certain packet which is exactly truncated after the tag field, the scrambling circuit 100 may generate the scrambled packet Pᵢₙ which merely comprises the destination address field DMAC, the source address field SMAC and the tag fields CPUTAG, OTAG and ITAG to the tested circuit 130, to thereby determine whether the tested circuit 130 is able to properly handle such conditions. For example, the pattern control signal PATTEN may be configured as 4′b0001 and the scrambling circuit 100 may take a total length of the destination address field DMAC, the source address field SMAC and the tag fields CPUTAG, OTAG and ITAG (e.g. 28 bytes) as a fixed length of the split packet (e.g. frag_len is fixed as 28), to make the split packet generated by the scrambling circuit 100 comprise the destination address field DMAC, the source address field SMAC and the tag fields CPUTAG, OTAG and ITAG only.

In some embodiments, the checking circuit 140 may perform statistical analysis on the scrambled packets {Pᵢₙ} output from the scrambling circuit 100 to obtain at least one first statistical result, and perform statistical analysis on the output packets {Pₒᵤₜ₁}, {Pₒᵤₜ₂}, . . . and {Pₒᵤₜₙ} output from the tested circuit 130 to obtain at least one second statistical result, where the checking circuit 140 may compare the at least one first statistical result and the at least one second statistical result to determine whether they are matched, in order to verify operations of the tested circuit 130 (e.g. packet handling/transferring of a prototype of the switch chip).

As for the scrambled packets {Pᵢₙ} output from the scrambling circuit 100, the checking circuit 140 may perform statistical analysis of a total packet count D_total_cnt of packets having source addresses at an input port of the tested circuit 130, having destination addresses at a range of output ports of the tested circuit 130 (e.g. P1 to Pn), having packet lengths conforming to the specific network communication specification, having correct check codes (e.g. contents of the checking field FCS), and/or having IPGs conforming to the specific network communication specification in front of the packets. In addition, the checking circuit 140 may perform statistical analysis on the destination address corresponding to each port to obtain a packet count D_P_cnt(k) corresponding to each port, where k represents any integer within an interval [1, n]. As for the output packet {Pₒᵤₜ₁}, {Pₒᵤₜ₂}, . . . and {Pₒᵤₜₙ} output from the tested circuit 130, the checking circuit 140 may perform corresponding statistical operations to obtain a total packet count S_total_cnt of all ports and packet counts S_P_cnt(k) respectively corresponding to these ports. Thus, the total packet count D_total_cnt and the packet counts D_P_cnt(k) respectively corresponding to these ports may be taken as an expected statistical result (e.g. the first statistic result mentioned above), and the total packet count S_total_cnt and the packet counts S_P_cnt(k) respectively corresponding to these ports may be taken as a realistic statistical result (e.g. the second statistical result mentioned above), where the checking circuit 140 may compare the expected statistical result and the realistic statistical result (e.g. determining whether D_total_cnt is equal to S_total_cnt and whether D_P_cnt(k) is equal to S_P_cnt(k)), to determine whether the tested circuit 130 (e.g. the prototype circuit of the switch chip) is able to correctly handle various types of scrambled packets.

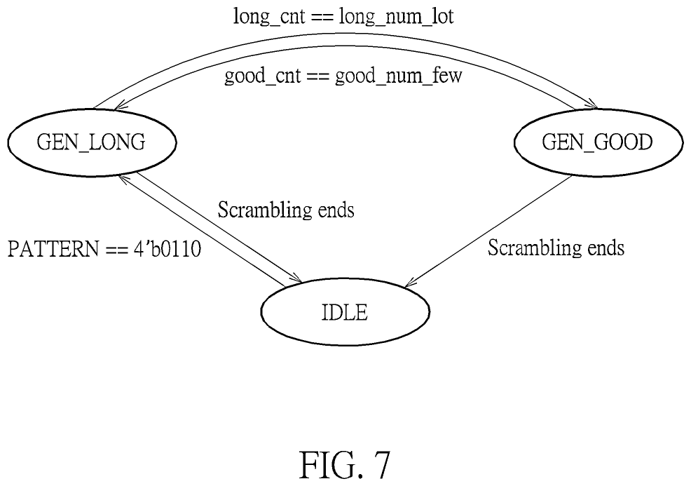

FIG. 7 is a diagram illustrating a control scheme when setting the pattern control signal PATTEN as 4′b0110 according to an embodiment of the present invention. In particular, the scrambling circuit 100 operating under this mode can generate a log of long packets and few normal packets, where numbers of the long packets and the normal packets may be controlled by random numbers generated by the random number generator 120. For example, the random number generator 120 may generate a length random number long_len within the interval [1519, max_long_len], generate an IPG random number ipg_len within the interval [ipg_min, ipg_max], generate a long packet random number long_num_lot within an interval [32, 255], and generate a normal packet random number good_num_few within an interval [1, 31].

When the scrambling circuit 100 detects that PATTERN is equal to 4′b0110, the scrambling circuit 100 may enter a long packet state GEN_LONG from an idle state IDLE. When the rising edge of the receiving control signal rxdv is detected, the scrambling circuit 100 may pull up the transmitting control signal txen and start counting to generate a counting result len_cnt, where the counting result len_cnt may represent a cycle number of the transmitting control signal txen at the high level. When the counting result len_cnt reaches long_len, the scrambling circuit 100 may pull down the transmitting control signal txen, where data and original packets (e.g. the standard packets P_{orig}) output from the scrambling circuit 100 during this period are consistent and kept unchanged. A long packet having a length equal to long_len may be sent, and a long packet counting result long_cnt is increased by one.

After the transmitting control signal txen is pulled down, the scrambling circuit 100 may start counting to generate a counting result ipg_cnt. When the counting result ipg_cnt is equal to the IPG random number ipg_len, an IPG having a length equal to ipg_len is sent.

The scrambling circuit 100 may determine whether the long packet counting result long_cnt reaches the long packet random number long_num_lot. If the long packet counting result long_cnt is not equal to the long packet random number long_num_lot, it means that operations of sending long packets are not finished, the scrambling circuit 100 may keep sending the long packets, and the random number generator 120 may generate a new random number to update long_len (e.g. making lengths of respective long packets be randomly distributed). If the long packet counting result long_cnt is equal to the long packet random number long_num_lot, it means that a target number of long packets have been sent, and the scrambling circuit 100 may enter a normal packet state GEN_GOOD from the long packet state GEN_LONG to start sending normal packets.

In the normal packet state GEN_GOOD, when the rising edge of the receiving control signal rxdv is detected, the scrambling circuit 100 may pull up the transmitting control signal txen and start counting to generate the counting result len_cnt. When the counting result len_cnt reaches a default value good_len, the scrambling circuit 100 may pull down the transmitting control signal txen, where data and original packets (e.g. the standard packets P_{orig}) output from the scrambling circuit 100 during this period are consistent and kept unchanged. A normal packet having a length equal to good_len may be sent, and a normal packet counting result good_cnt is increased by one.

The scrambling circuit 100 may determine whether the normal packet counting result good_cnt reaches the normal packet random number good_num_few. If the normal packet counting result good_cnt is not equal to the normal packet random number good_num_few, it means that operations of sending normal packets are not finished, and the scrambling circuit 100 may keep sending the normal packets. If the normal packet counting result good_cnt is equal to the normal packet random number good_num_few, it means that a target number of normal packets have been sent, and the scrambling circuit 100 may enter the long packet state GEN_LONG from the normal packet state GEN_GOOD to start sending long packets.

As mentioned above, the scrambling circuit 100 may be continuously switched between the long packet state GEN_LONG and the normal packet state GEN_GOOD during the period of operating in this mode, until scrambling operations ends. For example, when the scrambling circuit 100 detects that the pattern control signal PATTERN is switched to another value such as 4′b0000, the scrambling circuit 100 may return to the idle state IDLE.

To summarize, the system and the method provided by the embodiments of the present invention can utilize a scrambling circuit to scramble original packets (e.g. packets conforming to specification requirement), in order to generate permutations and combinations of various types of scrambled packets. Thus, the present invention can perform FPGA prototype verification on a prototype circuit of a switch chip before manufacturing the switch chip, in order to ensure that the switch chip would not malfunction when receiving these packets which do not meet the specification requirement in realistic application scenarios. In addition, the embodiments of the present invention will not greatly increase additional costs. Thus, the present invention can solve the problem of the related art without introducing any side effect or in a way that is less likely to introduce side effects.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A system for performing field programmable gate array (FPGA) prototype verification on a tested circuit, wherein the system comprises the tested circuit, and the system further comprises:
a packet generator, configured to output one or more standard packets, wherein a length of each of the one or more standard packets falls within a standard range;
a scrambling circuit, coupled to the packet generator and the tested circuit, configured to receive the one or more standard packets, and generate one or more scrambled packets according to the one or more standard packets for being output to the tested circuit, to make the tested circuit generate one or more output packets according to the one or more scrambled packets, wherein a length of any of the one or more scrambled packets falls outside the standard range; and
a checking circuit, coupled to the scrambling circuit and the tested circuit, configured to receive the one or more scrambled packets and the one or more output packets, and verify operations of the tested circuit according to the one or more scrambled packets and the one or more output packets;
wherein the scrambling circuit, the tested circuit and the checking circuit are implemented on an FPGA.

2. The system of claim 1, wherein the scrambling circuit splits up at least one standard packet of the one or more standard packets into multiple split packets, a length of each of the multiple split packets is less than a minimum length within the standard range, and the one or more scrambled packets comprise the multiple split packets.

3. The system of claim 2, wherein the scrambling circuit replaces a source address of the at least one standard packet by at least one replacement source address to determine a source address of at least one split packet of the multiple split packets, or replaces a destination address of the at least one standard packet by at least one replacement destination address to determine a destination address of at least one split packet of the multiple split packets.

4. The system of claim 2, wherein the scrambling circuit splits up the at least one standard packet into multiple split packets according to multiple random numbers within a predetermined range, to make lengths of the multiple split packets be respectively equal to the multiple random numbers.

5. The system of claim 2, wherein the scrambling circuit splits up the at least one standard packet into multiple split packets according to a fixed number, to make a length of each of the multiple split packet be equal to the fixed number.

6. The system of claim 5, wherein each standard packet of the one or more standard packets comprises a destination address field, a source address field, multiple tag field, a length field, a data field and a check field, a total length of the destination address field, the source address field and the multiple tag field is equal to a predetermined byte count, and the scrambling circuit sets the fixed number by the predetermined byte count to make at least one split packet of the multiple split packets comprise the destination address field, the source address field and the multiple tag field only.

7. The system of claim 2, wherein the scrambling circuit splits up the at least one standard packet into multiple split packets according to at least one random number within a predetermined range, to make an inter-packet gap (IPG) between any two adjacent packets of the multiple split packets be equal to the at least one random number.

8. The system of claim 1, wherein the scrambling circuit reduces a length of at least one standard packet of the one or more standard packets by one byte to generate at least one short packet, and the one or more scrambled packets comprise the at least one short packet.

9. The system of claim 1, wherein the scrambling circuit connects multiple standard packets of the one or more standard packets into at least one long packet, to make a length of the at least one long packet be greater than a maximum length within the standard range, and the one or more scrambled packets comprise the at least one long packet.

10. The system of claim 9, wherein the scrambling circuit connects the multiple standard packets of the one or more standard packets into the at least one long packet according to at least one random number within a predetermined range, to make a length of the at least one long packet be equal to the at least one random number.

11. The system of claim 1, wherein the one or more scrambled packet comprise at least two of at least one split packet, at least one short packet, at least one long packet and at least one normal packet, a length of the at least one split packet is less than a minimum length within the standard range, a length of the at least one short packet is equal to a length of at least one standard packet of the one or more standard packet minus one byte, and the at least one normal packet is equal to any of the one or more standard packets.

12. A method for performing field programmable gate array (FPGA) prototype verification on a tested circuit, comprising:
utilizing a packet generator to output one or more standard packets, wherein a length of each of the one or more standard packets falls within a standard range;
utilizing a scrambling circuit to receive the one or more standard packets and generate one or more scrambled packets according to the one or more standard packets, wherein a length of any of the one or more scrambled packets falls outside the standard range;
utilizing the tested circuit to receive the one or more scrambled packets and generate one or more output packets according to the one or more scrambled packets; and
utilizing a checking circuit to receive the one or more scrambled packets and the one or more output packets, and utilizing the checking circuit to verify operations of the tested circuit according to the one or more scrambled packets and the one or more output packets;
wherein the scrambling circuit, the tested circuit and the checking circuit are implemented on an FPGA.

13. The method of claim 12, wherein utilizing the scrambling circuit to receive the one or more standard packets and generate the one or more scrambled packets according to the one or more standard packets comprises:
utilizing the scrambling circuit to split up at least one standard packet of the one or more standard packets into multiple split packets;
wherein a length of each of the multiple split packets is less than a minimum length within the standard range, and the one or more scrambled packets comprise the multiple split packets.

14. The method of claim 13, wherein utilizing the scrambling circuit to split up the at least one standard packet of the one or more standard packets into the multiple split packets comprises:
utilizing the scrambling circuit to replace a source address of the at least one standard packet by at least one replacement source address to determine a source address of at least one split packet of the multiple split packets, or utilizing the scrambling circuit to replace a destination address of the at least one standard packet by at least one replacement destination address to determine a destination address of at least one split packet of the multiple split packets.

15. The method of claim 13, wherein utilizing the scrambling circuit to split up the at least one standard packet of the one or more standard packets into the multiple split packets comprises:
utilizing the scrambling circuit to split up the at least one standard packet into multiple split packets according to multiple random numbers within a predetermined range, to make lengths of the multiple split packets be respectively equal to the multiple random numbers.

16. The method of claim 13, wherein utilizing the scrambling circuit to split up the at least one standard packet of the one or more standard packets into the multiple split packets comprises:
utilizing the scrambling circuit to split up the at least one standard packet into multiple split packets according to a fixed number, to make a length of each of the multiple split packet be equal to the fixed number;
wherein each standard packet of the one or more standard packets comprises a destination address field, a source address field, multiple tag field, a length field, a data field and a check field, a total length of the destination address field, the source address field and the multiple tag field is equal to a predetermined byte count, and the scrambling circuit sets the fixed number by the predetermined byte count to make at least one split packet of the multiple split packets comprise the destination address field, the source address field and the multiple tag field only.

17. The method of claim 13, wherein utilizing the scrambling circuit to split up the at least one standard packet of the one or more standard packets into the multiple split packets comprises:
utilizing the scrambling circuit to split up the at least one standard packet into multiple split packets according to at least one random number within a predetermined range, to make an inter-packet gap (IPG) between any two adjacent packets of the multiple split packets be equal to the at least one random number.

18. The method of claim 12, wherein utilizing the scrambling circuit to split up the at least one standard packet of the one or more standard packets into the multiple split packets comprises:
utilizing the scrambling circuit to reduce a length of at least one standard packet of the one or more standard packets by one byte to generate at least one short packet;
wherein the one or more scrambled packets comprise the at least one short packet.

19. The method of claim 12, wherein utilizing the scrambling circuit to split up the at least one standard packet of the one or more standard packets into the multiple split packets comprises:
utilizing the scrambling circuit to connect multiple standard packets of the one or more standard packets into at least one long packet, to make a length of the at least one long packet be greater than a maximum length within the standard range;
wherein the one or more scrambled packets comprise the at least one long packet.

20. The method of claim 12, wherein the one or more scrambled packet comprise at least two of at least one split packet, at least one short packet, at least one long packet and at least one normal packet, a length of the at least one split packet is less than a minimum length within the standard range, a length of the at least one short packet is equal to a length of at least one standard packet of the one or more standard packet minus one byte, and the at least one normal packet is equal to any of the one or more standard packets.
